(19) United States
(12) Patent Application Publication
(10) Pub. No.: US 2025/0230344 A1
(43) Pub. Date: Jul. 17, 2025

(54) ADHESIVE FILM, ADHESIVE TAPE, ADHESIVE TAPE WITH RELEASE FILM, SEMICONDUCTOR DEVICE MANUFACTURING METHOD AND SEMICONDUCTOR DEVICE

(71) Applicant: Resonac Corporation, Minato-ku, Tokyo (JP)

(72) Inventors: Akiko HAYASHIDE, Minato-ku, Tokyo (JP); Ryosuke KIMURA, Minato-ku, Tokyo (JP); Tsuyoshi TAZAWA, Minato-ku, Tokyo (JP); Hiroyuki ISHIGE, Minato-ku, Tokyo (JP)

(21) Appl. No.: 18/854,548

(22) PCT Filed: Jun. 28, 2023
(86) PCT No.: PCT/JP2023/024048

§ 371 Date: Oct. 7, 2024

(30) Foreign Application Priority Data
Nov. 29, 2022 (JP) 2022-190392

(51) Int. Cl. C09J 7/35; C09J 5/06; C09J 7/20; H01L 23/00

(52) U.S. Cl. CPC C09J 7/35; C09J 5/06; C09J 7/201; C09J 2203/326; C09J 2301/122; C09J 2301/304; C09J 2301/416; H01L 24/73; H01L 2224/73204

(57) ABSTRACT

An adhesive film used for joining a semiconductor chip and a base and sealing a gap between the semiconductor chip and the base, the adhesive film being a single layer film formed from an adhesive composition having photocurability and thermosetting properties.

### TECHNICAL FIELD

The present invention relates to an adhesive film, an adhesive tape, a release film-attached adhesive tape, a method for producing a semiconductor device, and a semiconductor device.

### BACKGROUND ART

Wire bonding systems of using fine metal wires such as gold wires have been hitherto widely applied to connect semiconductor chips and substrates. Meanwhile, in order to respond to the requests for higher functionalization, higher integration, higher speed, and the like for semiconductor devices, a flip-chip connection system (FC connection system) in which a semiconductor chip and a substrate are directly connected by forming conductive protrusions called bumps on the semiconductor chip or the substrate, is becoming widespread.

For example, with regard to the connection between a semiconductor chip and a substrate, a COB (Chip On Board) type connection system that is actively used in BGA (Ball Grid Array), CSP (Chip Size Package), and the like, also corresponds to the FC connection system. In addition, the FC connection system is also widely used in a COC (Chip On Chip) type connection system in which semiconductor chips are connected by forming connecting parts (for example, bumps and wiring lines) on the semiconductor chips.

In packages where further size reduction, thickness reduction, and high functionalization are strongly required, chip stack type packages, POP (Package On Package), TSV (Through-Silicon Via), and the like, in which chips are stacked into multi-stages by using the above-mentioned connection systems, are also beginning to become widespread. Since such a technology of stacking into multi-stages allows three-dimensional arrangement of semiconductor chips and the like, packages can be made smaller as compared to techniques of arranging semiconductor chips and the like two-dimensionally. In addition, since the technology of stacking into multi-stages is also effective in improving semiconductor performance, reducing noise, reducing mounting area, and saving electric power, the technology is attracting attention as a next-generation semiconductor wiring technology.

From the viewpoint of improving productivity, COW (Chip On Wafer) by which semiconductor packages are produced by pressure-bonding (connecting) semiconductor chips on a semiconductor wafer and then singulating the semiconductor wafer, is also attracting attention. From a similar viewpoint, a gang bonding system in which a plurality of semiconductor chips are aligned and temporarily bonded on a semiconductor wafer or a map board, and then the plurality of semiconductor chips are permanently pressure-bonded all at once to secure connection, is also attracting attention.

For the connection between connecting members such as semiconductor chips as described above, thermosetting adhesive films that exhibit moderate fluidity at the temperature at the time of connection are used, and the adhesive films are cured by performing heating at the time of connection (at the time of pressure-bonding), thereby connecting the connecting members together (see, for example, Patent Literature 1).

### CITATION LIST

### Patent Literature

Patent Literature 1: Japanese Unexamined Patent Publication No. 2008-294382

### SUMMARY OF INVENTION

### Technical Problem

In recent years, along with high functionalization and high integration of packages, the gaps between layers and the pitch between wiring lines have become narrower, and therefore, a fillet (overflowing part) is becoming more likely to be formed as the adhesive having fluidity at the time of connection overflows from the edges of connecting members (for example, semiconductor chips). Since the fillet may cause damage to the connecting members, there is a demand for the development of a technique for reducing the amount of fillet generated while ensuring conductivity (connection reliability) between connecting members.

Thus, it is a main object of the present invention to provide an adhesive film for semiconductors that can suppress the amount of fillet generated.

### Solution to Problem

The present invention provides the following [1] to [14].

[1] An adhesive film used for joining a semiconductor chip and a base and sealing a gap between the semiconductor chip and the base, the adhesive film being a single layer film formed from an adhesive composition having photocurability and thermosetting properties.

[2] The adhesive film according to [1], in which the adhesive composition contains a photopolymerizable compound, a photopolymerization initiator, a thermosetting resin, and a thermal curing agent.

[3] The adhesive film according to [2], in which the photopolymerizable compound is a radically polymerizable compound, and the photopolymerization initiator is a photoradical polymerization initiator.

[4] The adhesive film according to [3], in which the radically polymerizable compound includes a (meth)acrylic compound.

[5] The adhesive film according to any one of [2] to [4], in which the thermosetting resin includes an epoxy resin.

[6] The adhesive film according to [5], in which the thermal curing agent includes an imidazole-based curing agent.

[7] The adhesive film according to [6], in which the imidazole-based curing agent has a triazine ring.

[8] The adhesive film according to any one of [2] to [7], in which a mass ratio of a content of the thermosetting resin with respect to a content of the photopolymerizable compound in the adhesive composition is 3 to 11.

[9] An adhesive tape including: the adhesive film according to any one of [1] to [8]; and a back-grinding tape provided on the adhesive film.

[10] A release film-attached adhesive tape including: the adhesive tape according to [9]; and a release film provided on the adhesive tape, the release film being provided on an opposite side of the back-grinding tape as viewed from the adhesive film.

[11] A method for producing a semiconductor device, the method including: a light irradiation step of irradiating the adhesive film according to any one of [1] to [8] with light; and a step of heating and joining a semiconductor chip and a base for mounting the semiconductor chip, in a state in which the semiconductor chip and the base are arranged, with the adhesive film after light irradiation interposed therebetween, such that connecting parts thereof face each other, in which the light irradiation step is carried out in a state in which the adhesive film is stuck to a connecting surface of the semiconductor chip or a precursor thereof, or a connecting surface of the base or a precursor thereof.

[12] The method for producing a semiconductor device according to [11], further including: a lamination step of preparing an adhesive tape including the adhesive film and a back-grinding tape provided on the adhesive film, and sticking the adhesive tape from a side of the adhesive film to a connecting surface of a precursor of the semiconductor chip or a precursor of the base; and a back-grinding step of grinding the precursor to which the adhesive tape is stuck, from an opposite side of the adhesive tape.

[13] The method for producing a semiconductor device according to [12], in which the light irradiation step is carried out after removing the back-grinding tape after the back-grinding step.

[14] A semiconductor device including: a semiconductor chip having a first connecting part; a base having a second connecting part electrically connected to the first connecting part; and a sealing part adhering the semiconductor chip to the base and filling a gap between the semiconductor chip and the base, in which the sealing part is a cured product of the adhesive film according to any one of [1] to [8].

### Advantageous Effects of Invention

According to the present invention, an adhesive film for semiconductors that can suppress the amount of fillet generated, can be provided.

### BRIEF DESCRIPTION OF DRAWINGS

FIG. 1 is a schematic cross-sectional view illustrating one embodiment of a release film-attached adhesive tape according to the present invention.

(a) in FIG. 2 is a schematic cross-sectional view illustrating one embodiment of a semiconductor device according to the present invention, and (b) in FIG. 2 is a schematic cross-sectional view illustrating another embodiment of the semiconductor device according to the present invention.

FIG. 3 is a schematic cross-sectional view illustrating another embodiment of the semiconductor device according to the present invention.

FIG. 4 is a process cross-sectional view schematically illustrating one embodiment of a method for producing a semiconductor device according to the present invention.

FIG. 5 is a process cross-sectional view schematically illustrating one embodiment of the method for producing a semiconductor device according to the present invention.

FIG. 6 is a process cross-sectional view schematically illustrating one embodiment of the method for producing a semiconductor device according to the present invention.

FIG. 7 is a process cross-sectional view schematically illustrating one embodiment of the method for producing a semiconductor device according to the present invention.

FIG. 8 is a process cross-sectional view schematically illustrating one embodiment of the method for producing a semiconductor device according to the present invention.

FIG. 9 is a process cross-sectional view schematically illustrating one embodiment of the method for producing a semiconductor device according to the present invention.

FIG. 10 is a process cross-sectional view schematically illustrating one embodiment of the method for producing a semiconductor device according to the present invention.

### DESCRIPTION OF EMBODIMENTS

According to the present specification, the term “(meth)acryl” means at least one of acryl and methacryl corresponding thereto. The same also applies to other similar expressions such as “(meth)acryloyl” and “(meth)acrylate”. In addition, a numerical value range expressed by using the term “to” represents a range including the numerical values described before and after the term “to” as the minimum value and the maximum value, respectively. With regard to a numerical value range described in the present specification, the upper limit value or the lower limit value of the numerical value range may be replaced with a value indicated in the Examples. Furthermore, upper limit values and lower limit values that are described individually can be combined arbitrarily. Unless particularly stated otherwise, the materials that will be mentioned below may be used singly, or two or more kinds thereof may be used in combination. In a case where there are a plurality of substances corresponding to each component in the composition, unless particularly stated otherwise, the content of each component in the composition means the total amount of the plurality of substances present in the composition.

Embodiments of the present invention will be described in detail below with reference to the drawings as needed. In the drawings, the same or equivalent parts are assigned with the same reference numerals, and duplicate descriptions will not be repeated. In addition, unless particularly stated otherwise, the positional relationships such as upper, lower, right, and left are based on the positional relationships shown in the drawings. Furthermore, the dimensional ratios in the drawings are not limited to the ratios shown in the drawings.

### <Adhesive Film>

An adhesive film according to one embodiment is an adhesive film used for joining a semiconductor chip and a base and sealing a gap between the semiconductor chip and the base, and is a single layer film formed from an adhesive composition having photocurability and thermosetting properties.

Since the above-described adhesive film has photocurability, the film-shaped adhesive easily becomes partially fluidized by light irradiation. Specifically, the fluidity of the adhesive constituting the adhesive film can be lowered by, for example, sticking the above-described adhesive film to one of two connecting members (a semiconductor chip, a base, or precursors thereof) and then performing light irradiation. Furthermore, in a method of curing by light irradiation, it is possible to easily adjust fluidity to a desired level by adjusting the type of the components to be contained in the adhesive film and the conditions for light irradiation as compared with a method of curing by heating or the like. Therefore, when the adhesive film is used, excessive flow of the adhesive can be suppressed while maintaining the fluidity required for connection between the connecting members, and as a result, the amount of fillet generated can be suppressed. Furthermore, since the above-described adhesive film has photocurability as well as thermosetting properties, the adhesive film can be further cured (thermally cured) by heating after photocuring, and can join the connecting members together with sufficient strength.

In addition, as a result of investigations of the present inventors, it has been made clear that in an adhesive film having a multilayer configuration that includes a layer having no photocurability and a layer having photocurability, the generation of fillet can be suppressed as is the case of the adhesive film of the above-described embodiment; however, voids are more likely to be generated than in the adhesive film of the above-described embodiment. In other words, when the adhesive film of the above-described embodiment is used, the generation of voids tends to be reduced as compared with an adhesive film having a multilayer configuration that includes a layer having no photocurability and a layer having photocurability.

### (Adhesive Composition)

An adhesive composition constituting the adhesive film contains, for example, a photopolymerizable compound, a photopolymerization initiator, a thermosetting resin, and a thermal curing agent. Here, the “photopolymerizable compound” means a compound that is polymerized by an active species (a radical, a cation, or an anion) generated by a photopolymerization initiator upon irradiation with light (for example, ultraviolet light), and the “thermosetting resin” means a compound that is cured by heat through a reaction with a thermal curing agent.

### [Photopolymerizable Compound]

The photopolymerizable compound may be a radically polymerizable compound, may be a cationically polymerizable compound, or may be an anionically polymerizable compound. The polymerizability of the photopolymerizable compound may be selected based on the relationship with the curability of the thermosetting resin and the thermal curing agent so as not to inhibit the reaction between the thermosetting resin and the thermal curing agent. For example, in a case where the thermosetting resin has cationic curability or anionic curability, it is preferable to use a radically polymerizable compound as the photopolymerizable compound.

From the viewpoint of the reaction rate, the photopolymerizable compound is preferably a radically polymerizable compound. In this case, a photoradical polymerization initiator is used as the photopolymerization initiator.

Examples of the radically polymerizable compound include a (meth)acrylic compound and a vinyl compound. From the viewpoint of being excellent in terms of durability, electrical insulation properties, and heat resistance, the radically polymerizable compound is preferably a (meth)acrylic compound. The (meth)acrylic compound may be a compound having one or more (meth)acryloyl groups in the molecule. As the (meth)acrylic compound, for example, (meth)acrylic compounds containing a skeleton of bisphenol A type, bisphenol F type, naphthalene type, phenol novolac type, cresol novolac type, phenol aralkyl type, biphenyl type, triphenylmethane type, dicyclopentadiene type, fluorene type, adamantane type, or isocyanuric acid type; various polyfunctional (meth)acrylic compounds (excluding (meth)acrylic compounds containing the above-described skeletons); and the like can be used. Examples of the polyfunctional (meth)acrylic compounds include pentaerythritol tri(meth)acrylate, dipentaerythritol poly(meth)acrylates (dipentaerythritol penta(meth)acrylate, dipentaerythritol hexa(meth)acrylate, and the like), and trimethylolpropane di(meth)acrylate. Among these, a polyfunctional (meth)acrylic compound is preferred, and a dipentaerythritol poly(meth)acrylate is more preferred. The number of functional groups (number of (meth)acryloyl groups) of the polyfunctional (meth)acrylic compound is preferably 2 to 8, more preferably 3 to 7, and even more preferably 4 to 6.

The molecular weight of the photopolymerizable compound is, for example, 400 to 2000. The molecular weight of the photopolymerizable compound is preferably less than 2000, and more preferably 1000 or less. As the molecular weight of the photopolymerizable compound is smaller, the reaction easily proceeds, and the curing reaction ratio is increased.

The photopolymerizable compounds can be used singly or in combination of two or more kinds thereof.

From the viewpoint of further reducing the amount of fillet generated, the content of the photopolymerizable compound is preferably 1% by mass or more, more preferably 3% by mass or more, and even more preferably 5% by mass or more, based on the total amount of the adhesive composition. From the viewpoint of improving sealing properties and from the viewpoint of suppressing the generation of voids, the content of the photopolymerizable compound is preferably 10% by mass or less, more preferably 7% by mass or less, or even more preferably 5% by mass or less, based on the total amount of the adhesive composition. From these viewpoints, the content of the photopolymerizable compound is preferably 1 to 10% by mass, more preferably 3 to 7% by mass, and even more preferably 3 to 5% by mass, based on the total amount of the adhesive composition.

### [Photopolymerization Initiator]

The photopolymerization initiator can be selected depending on the type of the photopolymerizable compound and may be a photoradical polymerization initiator, a photocationic polymerization initiator, or a photoanionic polymerization initiator. As the photopolymerization initiator, a photoradical polymerization initiator is preferably used for the same reason as that for the photopolymerizable compound.

The photoradical polymerization initiator is a compound that is decomposed upon irradiation with, for example, light including a wavelength in the range of 150 to 750 nm, preferably light including a wavelength in the range of 254 to 405 nm, and more preferably light including a wavelength at 365 nm (for example, ultraviolet light), and generates free radicals. As the photoradical polymerization initiator, one compound may be used alone, or a plurality of kinds of compounds may be used in combination.

Examples of the photoradical polymerization initiator include an alkylphenone-based photopolymerization initiator, an α-aminoalkyl ketone-based photopolymerization initiator, and a phosphine oxide-based photopolymerization initiator. Among these, from the viewpoint of reactivity, an alkylphenone-based photopolymerization initiator is preferred, and an α-hydroxyacetophenone photopolymerization initiator is more preferred.

Examples of the alkylphenone-based photopolymerization initiator include 1-hydroxycyclohexyl phenyl ketone, 2,2-dimethoxy-1,2-diphenylethan-1-one, 2-hydroxy-2-methyl-1-phenylpropan-1-one, 1-[4-(2-hydroxyethoxy)-phenyl]-2-hydroxy-2-methyl-1-propan-1-one, and 2-hydroxy-1-{4-[4-(2-hydroxy-2-methylpropionyl)benzyl]phenyl}-2-methylpropan-1-one.

From the viewpoint of suppressing volatilization caused by heat at the time of film formation, sticking, and the like, the molecular weight of the photoradical polymerization initiator is preferably 400 or more (for example, 300 to 600).

From the viewpoint that it is easy to allow curing to sufficiently proceed, the content of the photopolymerization initiator in the adhesive composition is preferably 0.1 parts by mass or more, more preferably 0.5 parts by mass or more, and even more preferably 1.0 part by mass or more, with respect to 100 parts by mass of the photopolymerizable compound. From the viewpoint of suppressing shortening of the molecular chain due to rapid progress of the curing reaction and remaining of unreacted groups, the content of the photopolymerization initiator is preferably 5.0 parts by mass or less, more preferably 3.0 parts by mass or less, and even more preferably 1.5 parts by mass or less, with respect to 100 parts by mass of the photopolymerizable compound. From these viewpoints, the content of the photopolymerization initiator is preferably 0.1 to 5.0 parts by mass, more preferably 0.5 to 3.0 parts by mass, and even more preferably 0.5 to 1.5 parts by mass, with respect to 100 parts by mass of the photopolymerizable compound. From the same viewpoint as described above, the content of the photoradical polymerization initiator in the adhesive composition is preferably 0.1 to 5.0 parts by mass, more preferably 0.5 to 3.0 parts by mass, and even more preferably 0.5 to 1.5 parts by mass, with respect to 100 parts by mass of the radically polymerizable compound.

### [Thermosetting Resin]

Examples of the thermosetting resin include an epoxy resin, a phenol resin (except for the case of being contained as a curing agent), and an acrylic resin. Among these, an epoxy resin is preferably used. The content of the epoxy resin in the thermosetting resin is preferably 80% by mass or more, and more preferably 90% by mass or more, based on the total amount of the thermosetting resin. The content of the epoxy resin may be 100% by mass based on the total amount of the thermosetting resin.

The epoxy resin is a compound having two or more epoxy groups in the molecule. As the epoxy resin, for example, a bisphenol A type epoxy resin, a bisphenol F type epoxy resin, a naphthalene type epoxy resin, a phenol novolac type epoxy resin, a cresol novolac type epoxy resin, a phenol aralkyl type epoxy resin, a biphenyl type epoxy resin, a triphenylmethane type epoxy resin, a triphenolmethane type epoxy resin, a dicyclopentadiene type epoxy resin, and various polyfunctional epoxy resins can be used. These can be used singly or as mixtures of two or more kinds thereof. Among these, in a case where a triphenolmethane type epoxy resin (triphenolmethane skeleton-containing epoxy resin) is used, the amount of fillet generated tends to be further reduced.

Regarding the epoxy resin, from the viewpoint of suppressing the epoxy resin from being decomposed and generating volatile components at the time of connection at a high temperature, it is preferable to use an epoxy resin having a thermal weight loss rate of 5% or less at the temperature at the time of connection. For example, in a case where the temperature at the time of connection is 250° C., it is preferable to use an epoxy resin having a thermal weight loss rate at 250° C. of 5% or less, and in a case where the temperature at the time of connection is 300° C., it is preferable to use an epoxy resin having a thermal weight loss rate at 300° C. of 5% or less.

Regarding the epoxy resin, from the viewpoint that it is easy to suppress the occurrence of cracks and fissures on the film surface, an epoxy resin that is liquid at 25° C. (hereinafter, simply referred to as “liquid epoxy resin”) may also be used. Here, the phrase “liquid at 25° C.” means that the viscosity at 25° C. as measured with an E type viscometer is 400 Pa·s or less. Examples of the liquid epoxy resin include glycidyl ether of a bisphenol A type resin, glycidyl ether of a bisphenol AD type resin, glycidyl ether of a bisphenol S type resin, glycidyl ether of a bisphenol F type resin, glycidyl ether of a hydrogenated bisphenol A type resin, glycidyl ether of an ethylene oxide adduct bisphenol A type resin, glycidyl ether of a propylene oxide adduct bisphenol A type resin, glycidyl ether of a naphthalene resin, and a trifunctional or tetrafunctional glycidyl amine.

From the viewpoint that it is easy to suppress the occurrence of cracks and fissures on the film surface, the content of the liquid epoxy resin in the thermosetting resin is preferably 5% by mass or more, more preferably 10% by mass or more, and even more preferably 20% by mass or more, based on the total amount of the thermosetting resin. From the viewpoint that it is easy to suppress excessive increase in the tackiness of the film and from the viewpoint that it is easy to suppress edge fusion, the content of the liquid epoxy resin in the thermosetting resin is preferably 30% by mass or less, more preferably 20% by mass or less, or even more preferably 10% by mass or less, based on the total amount of the thermosetting resin. From these viewpoints, the content of the liquid epoxy resin in the thermosetting resin is preferably 5 to 30% by mass based on the total amount of the thermosetting resin.

The reactive functional group equivalent of the thermosetting resin (for example, epoxy equivalent of the epoxy resin) may be 100 to 3000 g/eq, or may be 100 to 2000 g/eq or 100 to 1500 g/eq. When the reactive functional group equivalent is in the above-described range, the balance between reactivity and fluidity during heating is likely to be satisfactory.

From the viewpoint that it is easy to suppress the occurrence of fillet, the content of the thermosetting resin in the adhesive composition is preferably 25% by mass or more, more preferably 30% by mass or more, and even more preferably 35% by mass or more, based on the total amount of the adhesive composition. From the viewpoint that satisfactory sealing properties are easily obtained and from the viewpoint that it is easy to suppress the generation of voids, the content of the thermosetting resin in the adhesive composition is preferably 50% by mass or less, more preferably 45% by mass or less, and even more preferably 40% by mass or less, based on the total amount of the adhesive composition. From these viewpoints, the content of the thermosetting resin in the adhesive composition is preferably 25 to 50% by mass based on the total amount of the adhesive composition.

The content of the above-described thermosetting resin may be set based on the relationship with the content of the photopolymerizable compound. When the mass ratio of the content of the thermosetting resin with respect to the content of the photopolymerizable compound in the adhesive composition is 3 to 11 in terms of mass ratio, high connection reliability is likely to be obtained, and the amount of fillet generated tends to be further reduced. From the viewpoint that the amount of fillet generated is further reduced, the above-described ratio may be 5 or more, 7 or more, or 9 or more, and in addition to the above-described effects, the ratio may be 10 or less from the viewpoint that satisfactory sealing properties are likely to be obtained, and from the viewpoint that the generation of voids is easily suppressed.

### [Thermal Curing Agent]

As the thermal curing agent, known curing agents that are known as curing agents for thermosetting resins can be used. The thermal curing agent also includes materials that are generally known as curing accelerators. In a case where an epoxy resin is used as the thermosetting resin, as the thermal curing agent, for example, a phenol resin-based curing agent, an acid anhydride-based curing agent, an amine-based curing agent, an imidazole-based curing agent, and a phosphine-based curing agent can be used. Among these, a phenol resin-based curing agent, an acid anhydride-based curing agent, an amine-based curing agent, and an imidazole-based curing agent exhibit flux activity that suppresses generation of an oxide film at the connecting parts, and therefore, the connection reliability can be improved by using these thermal curing agents. From the viewpoint that curing can be rapidly carried out in the case of performing heating at a low temperature, it is preferable to use an imidazole-based curing agent.

Examples of the imidazole-based curing agent include 2-2-phenyl-4-methylimidazole, 1-benzyl-2-phenylimidazole, methylimidazole, 1-benzyl-2-phenylimidazole, 1-cyanoethyl-2-undecylimidazole, 1-cyano-2-phenylimidazole, 1-cyanoethyl-2-undecylimidazole trimellitate 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazine isocyanuric acid adduct, 2-phenylimidazole isocyanuric acid adduct, 2-phenyl-4,5-dihydroxymethylimidazole, 2-phenyl-4-methyl-5-hydroxymethylimidazole, and an adduct of an epoxy resin and an imidazole. In addition, latent curing agents in which these curing agents are microencapsulated can also be used. These can be used singly or in combination of two or more kinds thereof. Among these, from the viewpoint that more satisfactory sealing properties are likely to be obtained, and from the viewpoint that the generation of voids is easily suppressed, a compound having a triazine ring is preferably used.

From the viewpoint that the curability at the time of heating is improved, the content of the thermal curing agent in the adhesive composition is preferably 1 part by mass or more, more preferably 2 parts by mass or more, and even more preferably 3 parts by mass or more, with respect to 100 parts by mass of the thermosetting resin. From the viewpoint that intervention of the adhesive composition into the space between the connecting parts can be made more difficult to occur, the content of the thermal curing agent in the adhesive composition is preferably 10 parts by mass or less, more preferably 7 parts by mass or less, and even more preferably 5 parts by mass or less, with respect to 100 parts by mass of the thermosetting resin. From these viewpoints, the content of the thermal curing agent in the adhesive composition is preferably 1 to 10 parts by mass with respect to 100 parts by mass of the thermosetting resin.

### [Other Components]

With regard to the adhesive composition, examples of components other than those described above include a thermoplastic resin and a filler.

A thermoplastic resin contributes to the improvement in heat resistance and the improvement in film-forming properties. Examples of the thermoplastic resin include a phenoxy resin, a polyimide resin, a polyamide resin, a polycarbodiimide resin, a cyanate ester resin, an acrylic resin, a polyester resin, a polyethylene resin, a polyether sulfone resin, a polyetherimide resin, a polyvinyl acetal resin, a urethane resin, and an acrylic rubber. Among these, from the viewpoint that excellent heat resistance and film-forming properties are likely to be obtained, a phenoxy resin, a polyimide resin, an acrylic rubber, a cyanate ester resin, and a polycarbodiimide resin are preferred, and a phenoxy resin, a polyimide resin, and an acrylic rubber are more preferred. These thermoplastic resins can be used singly or as mixture or copolymers of two or more kinds thereof.

The weight average molecular weight of the thermoplastic resin is, for example, 10000 or more and may be 20000 or more or 30000 or more. When such a thermoplastic resin is used, the heat resistance and film-forming properties of the adhesive composition can be further improved. From the viewpoint that an effect of improving heat resistance is likely to be obtained, the weight average molecular weight of the thermoplastic resin may be 1000000 or less or may be 500000 or less. From these viewpoints, the weight average molecular weight of the thermoplastic resin may be, for example, 10000 to 1000000. Incidentally, the weight average molecular weight as used in the present specification means a weight average molecular weight obtained when measured by using high performance liquid chromatography (manufactured by SHIMADZU CORPORATION, trade name: C-R4A), relative to polystyrene standards. For the measurement, for example, the following conditions can be used.
Detector: LV4000 UV Detector (manufactured by Hitachi, Ltd., trade name)
Pump: L6000 Pump (manufactured by Hitachi, Ltd., trade name)
Column: Gelpack GL-S300MDT-5 (two in total) (manufactured by Hitachi, Ltd., trade name)
Eluent: THF/DMF=1/1 (volume ratio)+LiBr (0.03 mol/L)+H3PO4 (0.06 mol/L)
Flow rate: 1 mL/min

From the viewpoint of having excellent stickability of the adhesive film to connecting members (for example, semiconductor chips), the glass transition temperature (Tg) of the thermoplastic resin is preferably 120° C. or lower, more preferably 100° C. or lower, and even more preferably 85° C. or lower. The above-described Tg is a Tg obtained when measured using a DSC (manufactured by PerkinElmer, Inc., trade name: DSC-7 type) under the conditions of a sample amount of 10 mg, a temperature increase rate of 10° C./min, and a measurement atmosphere of air.

From the viewpoint that the heat resistance and film-forming properties of the adhesive composition are likely to be improved, the content of the thermoplastic resin in the adhesive composition is preferably 5% by mass or more, more preferably 7% by mass or more, and even more preferably 10% by mass or more, based on the total amount of the adhesive composition. From the viewpoint of allowing the generation of fillet to be easily suppressed, the content of the thermoplastic resin in the adhesive composition is preferably 30% by mass or less, more preferably 25% by mass or less, and even more preferably 20% by mass or less, based on the total amount of the adhesive composition. From these viewpoints, the content of the thermoplastic resin in the adhesive composition is preferably 5 to 30% by mass based on the total amount of the adhesive composition.

A filler is effective for controlling the viscosity of the adhesive composition, the physical properties of a cured product of the adhesive composition, and the like. Specifically, by using a filler, suppression of void generation at the time of connection, reduction of the coefficient of moisture absorption of a cured product of the adhesive composition, and the like can be promoted. The filler may be an inorganic filler (inorganic particles) or an organic filler (organic particles). Examples of the inorganic filler include insulating inorganic fillers such as glass, silica, alumina, titanium oxide, mica, and boron nitride. Among these, it is preferable to use at least one selected from the group consisting of silica, alumina, titanium oxide, and boron nitride, and it is more preferable to use at least one selected from the group consisting of silica, alumina, and boron nitride. Examples of the organic filler include a resin filler (resin particles). Examples of the resin filler include polyurethane and polyimide. When a resin filler is used, flexibility at a high temperature such as 260° C. can be imparted. It is noted that an organic filler formed of a thermoplastic resin does not correspond to the above-described thermoplastic resin.

From the viewpoint of having more excellent insulation reliability, it is preferable that the filler is insulative. It is preferable that the adhesive composition does not contain a filler including a conductive material (conductive filler) such as silver, solder, or carbon black.

The physical properties of the filler may be adjusted as appropriate by a surface treatment. From the viewpoint that dispersibility or adhesive power is improved, the filler may be a filler that has been subjected to a surface treatment. Examples of the surface treatment agent include glycidyl-based (epoxy-based), amine-based, phenyl-based, phenylamino-based, (meth)acryl-based, and vinyl-based compounds.

The average particle size of the filler is, for example, 0.5 to 1.5 μm. The average particle size of the filler is preferably 1.5 μm or less from the viewpoint of preventing jamming at the time of flip-chip connection, and is more preferably 1.0 μm or less from the viewpoint of having excellent visibility (transparency). The average particle size of the filler is the particle size at a point corresponding to 50% of the volume when a cumulative frequency distribution curve based on the particle size is determined by taking the total volume of the particles as 100%, and the average particle size can be measured with a particle size distribution analyzer using a laser diffraction scattering method, or the like.

From the viewpoint that lowering of the heat dissipation properties is suppressed, and from the viewpoint that the generation of voids, an increase in the coefficient of moisture absorption, and the like are easily suppressed, the content of the filler in the adhesive composition is preferably 25% by mass or more, more preferably 30% by mass or more, and even more preferably 35% by mass or more, based on the total amount of the adhesive composition. From the viewpoint of suppressing the occurrence of jamming (trapping) of the filler at the connecting parts, the content of the filler in the adhesive composition is preferably 60% by mass or less, more preferably 55% by mass or less, and even more preferably 50% by mass or less, based on the total amount of the adhesive composition. From these viewpoints, the content of the filler in the adhesive composition is preferably 25 to 60% by mass based on the total amount of the adhesive composition.

In a case where the filler includes an inorganic filler and an organic filler, the content of the inorganic filler may be 60% by mass or more, 70% by mass or more, or 80% by mass or more, may be 98% by mass or less, 95% by mass or less, or 90% by mass or less, and may be 60 to 98% by mass, 70 to 95% by mass, or 80 to 90% by mass, based on the total amount of the filler in the adhesive composition.

The adhesive composition may further contain additives such as an oxidation inhibitor, a silane coupling agent, a titanium coupling agent, a leveling agent, and an ion trapping agent. These can be used singly or in combination of two or more kinds thereof. The contents of these may be adjusted as appropriate so that the effect of each additive is exhibited. The adhesive composition may include a flux agent that will be described below, and the content of the flux agent is preferably less than 0.5% by mass, more preferably less than 0.01% by mass, and even more preferably 0% by mass, based on the total amount of the adhesive composition. Particularly, in a case where the adhesive composition is radically polymerizable (radical-curable), curing of the adhesive composition is likely to be inhibited by the flux agent, and therefore, it is preferable that the adhesive composition does not include a flux agent. Incidentally, the flux agent is a compound having flux activity and is, for example, a compound having a carboxy group (mono- or polycarboxylic acid). As described above, an imidazole-based curing agent may also have flux activity; however, compounds that fall under the category of imidazole-based curing agents are not considered to fall under the category of the above-described flux agent. Specific examples of the flux agent such as described above include dicarboxylic acids such as succinic acid, glutaric acid, adipic acid, pimelic acid, suberic acid, azelaic acid, sebacic acid, undecanedioic acid, and dodecanedioic acid; and compounds obtained by substituting an electron-donating group at the 2-position of these dicarboxylic acids (for example, 2-methylglutaric acid).

The adhesive film described above can be produced by, for example, the following method. First, each of the components that constitute the adhesive film (a photopolymerizable compound, a photopolymerization initiator, a thermosetting resin, a thermal curing agent, a filler, a thermoplastic resin, additives, and the like) is added into an organic solvent, and the components are dissolved or dispersed by stirred mixing, kneading, or the like to prepare a coating liquid including an adhesive composition. Thereafter, the coating liquid is applied on a base material (a film or a tape) that has been subjected to a mold release treatment on at least one surface, by using a knife coater, a roll coater, an applicator, or the like to form a coating film. Next, the organic solvent is reduced from the coating film by heating. As a result, an adhesive film can be formed on the base material.

Regarding the organic solvent used for preparing the coating liquid, an organic solvent having characteristics that can uniformly dissolve or disperse each component is preferred, and examples thereof include dimethylformamide, dimethylacetamide, N-methyl-2-pyrrolidone, dimethyl sulfoxide, diethylene glycol dimethyl ether, toluene, benzene, xylene, methyl ethyl ketone, tetrahydrofuran, ethyl cellosolve, ethyl cellosolve acetate, butyl cellosolve, dioxane, cyclohexanone, and ethyl acetate. These organic solvents can be used singly or in combination of two or more kinds thereof. Stirred mixing and kneading at the time of preparing the coating liquid can be performed by, for example, using a stirrer, a Raikai mixer, a three-roll, a ball mill, a bead mill, or a Homodisper.

The base material is not particularly limited as long as it has heat resistance that can withstand the heating conditions at the time of volatilizing the organic solvent, and examples thereof include polyolefin films such as a polypropylene film and a polymethylpentene film; polyester films such as a polyethylene terephthalate film and a polyethylene naphthalate film; a polyimide film; and a polyetherimide film. The base material is not limited to a single layer base material formed from any of these films, and may be a multilayer film formed from two or more kinds of materials. The base material may also be a film subjected to a mold release treatment on the surface.

The drying conditions at the time of volatilizing the organic solvent from the coating film on the base material are preferably conditions in which the organic solvent is sufficiently volatilized, and specifically, it is preferable to perform heating at 50 to 200° C. for 0.1 to 90 minutes. Unless the voids or viscosity adjustment after mounting is affected, it is preferable that the organic solvent is removed to a level of 1.5% by mass or less with respect to the total amount of the adhesive composition.

### <Adhesive Tape and Release Film-Attached Adhesive Tape>

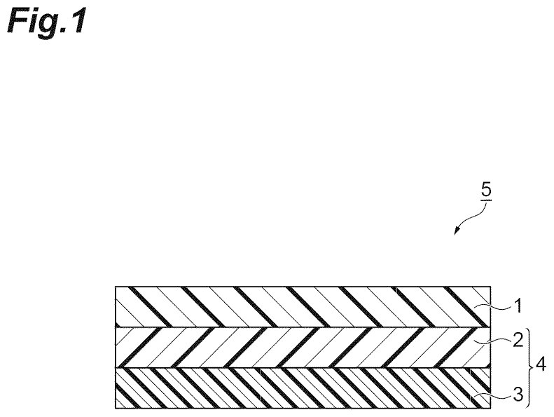

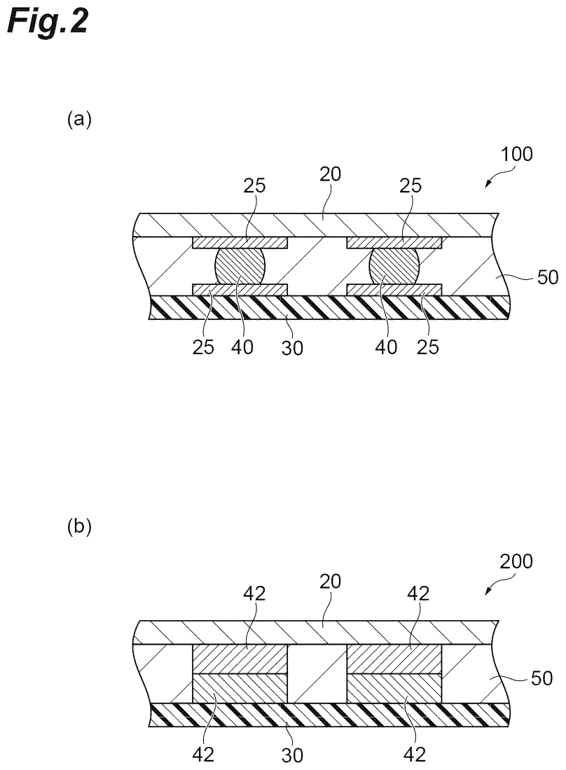

FIG. 1 is a schematic cross-sectional view illustrating a release film-attached adhesive tape according to one embodiment. The release film-attached adhesive tape 5 shown in FIG. 1 includes a release film 1, an adhesive film 2, and a base material 3. The base material 3 is provided on the adhesive film 2 and constitutes an adhesive tape 4 together with the adhesive film 2. That is, FIG. 1 discloses an adhesive tape 4 according to one embodiment, together with a release film-attached adhesive tape 5 according to one embodiment. The release film 1 is provided on the opposite side of the base material 3 as viewed from the adhesive film 2.

The release film 1 may be a film configured to be releasable from the adhesive film 2, and may be, for example, a film that has been subjected to a mold release treatment on the surface. The release film 1 may be a base material that is used for the production of the adhesive film 2. The release film 1 may be, for example, a film containing a polyolefin such as polypropylene or polymethylpentene; a polyester such as polyethylene terephthalate or polyethylene naphthalate; polyimide, or polyetherimide. The thickness of the release film 1 is not particularly limited, but may be, for example, 5 to 200 μm.

The adhesive film 2 is the adhesive film according to the above-described embodiment. The thickness of the adhesive film 2 may be set as appropriate based on the relationship with the height of the connecting part in the connecting member to which the adhesive film 2 is stuck before light irradiation. When the height of the above-described connecting part is designated as Y, and the thickness of the adhesive film 2 is designated as X, it is preferable that the relationship between X and Y satisfies 0.70X≤Y≤1.3X, and more preferably satisfies 0.80X≤Y≤1.2X, from the viewpoint of connectivity during pressure-bonding and the filling properties of the adhesive. From the viewpoint that a cured product of the adhesive composition is less likely to enter between the connecting parts, and the connection reliability is further improved, it is preferable that Y>X is satisfied. Specifically, the thickness of the adhesive film 2 may be 2 to 100 μm, or may be 6 to 100 μm, 8 to 60 μm, or 10 to 40 μm.

The base material 3 is, for example, a film or tape capable of supporting the adhesive film 2, and is preferably a back-grinding tape. The back-grinding tape is usually configured such that one principal surface side is a tacky adhesive layer; however, in this case, the back-grinding tape is provided on the adhesive film 2 such that the surface on the tacky adhesive layer side comes on the adhesive film 2 side (for example, such that the tacky adhesive layer and the adhesive film are in contact). The thickness of the base material 3 (for example, thickness of the back-grinding tape) may be 20 to 300 μm.

In a case where the above-mentioned base material that is used for the production of the adhesive film 2 is used as the base material 3 of the adhesive tape 4, a laminated body of a base material and an adhesive film obtained by the above-mentioned method for producing an adhesive film, that is, a method of applying a coating liquid on a base material, forming a coating film, and drying the coating film, may be used as it is as the adhesive tape 4. Alternatively, the adhesive tape 4 may be obtained by sticking the base material 3 to the adhesive film 2 (for example, laminating the adhesive film 2 and the base material 3). In a case where the base material 3 is a back-grinding tape, when the coating liquid is applied and dried on the tacky adhesive layer of the back-grinding tape, there is a possibility that there may be problems such as destruction of the tacky adhesive layer and component transfer between the tacky adhesive and the adhesive, and therefore, it is preferable to obtain the adhesive tape 4 by sticking a back-grinding tape to the adhesive film 2.

The release film-attached adhesive tape 5 may be obtained by sticking a release film 1 to the adhesive tape 4 (for example, laminating the adhesive tape 4 and the release film 1), or may be obtained by providing the adhesive film 2 on the release film 1 and then providing the base material 3 on the adhesive film 2.

### <Semiconductor Device>

Next, a semiconductor device that is produced using the adhesive film of the above-described embodiment will be described.

(a) in FIG. 2 is a schematic cross-sectional view illustrating one embodiment of the semiconductor device. The semiconductor device 100 shown in FIG. 2(a) includes: a semiconductor chip 20 and a base 30 for mounting the semiconductor chip, the semiconductor chip 20 and the base 30 facing each other; wiring lines (first connecting part and second connecting part) 25 arranged on the mutually facing surfaces of the semiconductor chip 20 and the base 30, respectively; connecting bumps 40 connecting the wiring lines 25 of the semiconductor chip 20 and the base 30 to each other; and a sealing part 50 formed from a cured product of an adhesive composition (adhesive composition constituting the adhesive film according to the above-described embodiment) that fills the gap between the semiconductor chip 20 and the base 30. The semiconductor chip 20 and the base 30 are flip-chip connected by the wiring lines 25 and the connecting bumps 40. The wiring lines 25 and the connecting bumps 40 are sealed by the cured product of the adhesive composition and are isolated from the external environment.

(b) in FIG. 2 is a schematic cross-sectional view illustrating another embodiment of the semiconductor device. The semiconductor device 200 shown in FIG. 2(b) includes: a semiconductor chip 20 and a base 30 facing each other; bumps (first connecting part and second connecting part) 42 arranged on the mutually facing surfaces of the semiconductor chip 20 and the base 30, respectively; and a sealing part 50 formed from a cured product of an adhesive composition (adhesive composition constituting the adhesive film according to the above-described embodiment) that fills the gap between the semiconductor chip 20 and the base 30. The semiconductor chip 20 and the base 30 are flip-chip connected by connecting the bumps 42 that face each other. The bumps 42 are sealed by the cured product of the adhesive composition and are isolated from the external environment.

The semiconductor chip 20 is not particularly limited, and a semiconductor chip formed of an elemental semiconductor composed of the same type of elements such as silicon or germanium, or a semiconductor chip formed of a compound semiconductor such as gallium arsenide or indium phosphide, can be used.

The base 30 is not particularly limited as long as it is used for loading the semiconductor chip 20, and examples thereof include a semiconductor chip, a semiconductor wafer, and a wiring circuit board.

Examples of the semiconductor chip that can be used as the base 30 are the same as the examples of the above-described semiconductor chip 20, and the same semiconductor chip as the semiconductor chip 20 may be used as the base 30.

The semiconductor wafer that can be used as the base 30 is not particularly limited, and a semiconductor wafer having a configuration in which a plurality of the semiconductor chips mentioned as examples of the above-described semiconductor chip 20 are linked may be used.

The wiring circuit board that can be used as the base 30 is not particularly limited, and a circuit board having wiring lines (wiring pattern) 25 formed on the surface of an insulating substrate containing glass epoxy, polyimide, polyester, ceramic, epoxy, bismaleimide triazine, or the like as a main component by removing unnecessary parts of a metal film by etching; a circuit board having wiring lines 25 formed on the surface of the above-described insulating substrate by metal plating or the like; a circuit board having wiring lines 25 formed on the surface of the above-described insulating substrate by printing a conductive substance; or the like can be used.

The connecting parts such as wiring lines 25 and bumps 42 contain gold, silver, copper, solder (main components are, for example, tin-silver, tin-lead, tin-bismuth, tin-copper, and tin-silver-copper), nickel, tin, lead, or the like as a main component, and may contain a plurality of metals.

Among the above-described metals, from the viewpoint of providing a package in which the connecting parts have excellent electrical conductivity and thermal conductivity, gold, silver, and copper are preferable, and silver and copper are more preferable. From the viewpoint of providing a package at reduced cost, silver, copper, and solder, which are inexpensive materials, are preferable, copper and solder are more preferable, and solder is even more preferable. When an oxide film is formed on the surface of metal at room temperature, productivity may decrease while cost may increase, and therefore, from the viewpoint of suppressing the formation of an oxide film, gold, silver, copper, and solder are preferable, gold, silver, and solder are more preferable, and gold and silver are even more preferable.

On the surface of the above-described wiring lines 25 and bumps 42, a metal layer containing gold, silver, copper, solder (main components are, for example, tin-silver, tin-lead, tin-bismuth, and tin-copper), tin, nickel, or the like as a main component, may be formed by, for example, plating. This metal layer may be composed only of a single component or may be composed of a plurality of components. In addition, the above-described metal layer may have a single layer structure or a structure in which a plurality of metal layers are stacked.

The semiconductor device may be such that a plurality of structures (packages) as shown in the semiconductor device 100 and the semiconductor device 200 of the above-described embodiments are stacked. In this case, the semiconductor device 100 and the semiconductor device 200 may be electrically connected to each other by means of bumps, wiring lines, and the like, which include gold, silver, copper, solder (main components are, for example, tin-silver, tin-lead, tin-bismuth, tin-copper, and tin-silver-copper), tin, nickel, or the like.

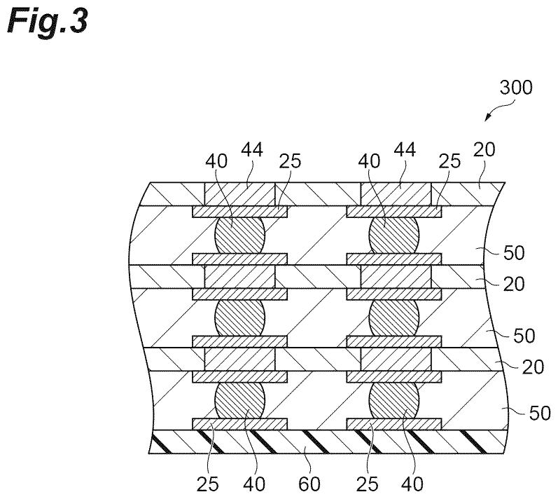

Regarding a technique of stacking a plurality of semiconductor devices, for example, a TSV (Through-Silicon Via) technology may be mentioned. An example of a semiconductor device obtained by stacking by the TSV technology is shown in FIG. 3. In a semiconductor device 500 shown in FIG. 3, as wiring lines 25 formed on an interposer 60 are connected to wiring lines 25 of a semiconductor chip 20 through connecting bumps 40, the semiconductor chip 20 and the interposer 60 are flip-chip connected. A gap between the semiconductor chip 20 and the interposer 60 is filled with a cured product of an adhesive, and the cured product constitutes a sealing part 50. On the surface on the opposite side of the interposer 60 in the above-described semiconductor chip 20, semiconductor chips 20 are repeatedly stacked, with wiring lines 25, connecting bumps 40, and sealing parts 50 interposed therebetween. The wiring lines 25 of the patterned surfaces on the front and back sides of the semiconductor chip 20 are connected to each other through electrodes 44 filling in the holes penetrating through the inside of the semiconductor chip 20. As the material of the through electrode 44, copper, aluminum, and the like can be used.

It is made possible by such a TSV technology to acquire signals even from the back side of the semiconductor chip, which is normally not used. In addition, since the through electrodes 44 vertically pass through the semiconductor chips 20, the distance between semiconductor chips 20 facing each other, and the distance between a semiconductor chip 20 and an interposer 60 can be shortened, and flexible connection is enabled. In such a TSV technology, the adhesive film of the above-described embodiment can be applied as an adhesive film for semiconductors between semiconductor chips 20 facing each other and between a semiconductor chip 20 and an interposer 60.

Furthermore, in bump forming methods with a high degree of freedom, such as an area bump chip technology, semiconductor chips can be directly mounted on a motherboard as they are, without using interposers. The adhesive film of the above-described embodiment can be applied even in a case where such semiconductor chips are mounted directly on a motherboard. The adhesive film of the above-described embodiment can also be applied when sealing gaps (voids) between substrates in a case where two wiring circuit substrates are stacked.

### <Method for Producing Semiconductor Device>

Next, a method for producing a semiconductor device using the adhesive film of the above-described embodiment will be described.

The method for producing a semiconductor device according to one embodiment includes, for example, a light irradiation step of irradiating an adhesive film with light; and a heating joining step of heating and joining a semiconductor chip and a base for mounting the semiconductor chip, in a state in which the semiconductor chip and the base are arranged such that the connecting parts thereof face each other, with the adhesive film after light irradiation interposed therebetween. The above-described light irradiation step is carried out in a state in which the adhesive film is stuck to a connecting surface of the semiconductor chip or a precursor thereof, or a connecting surface of the base or a precursor thereof. Here, the precursor of the semiconductor chip means a member that becomes a semiconductor chip through processing. A specific example of the precursor of the semiconductor chip is a semiconductor wafer. The same also applies to the precursor of the base.

In the following description, the method for producing a semiconductor device will be described by taking one embodiment of using a semiconductor wafer as a precursor of a semiconductor chip as an example. Incidentally, in the following description, a connecting surface means a surface on which a connecting part (wiring lines, bumps, and the like) to be connected in the heating joining step is provided.

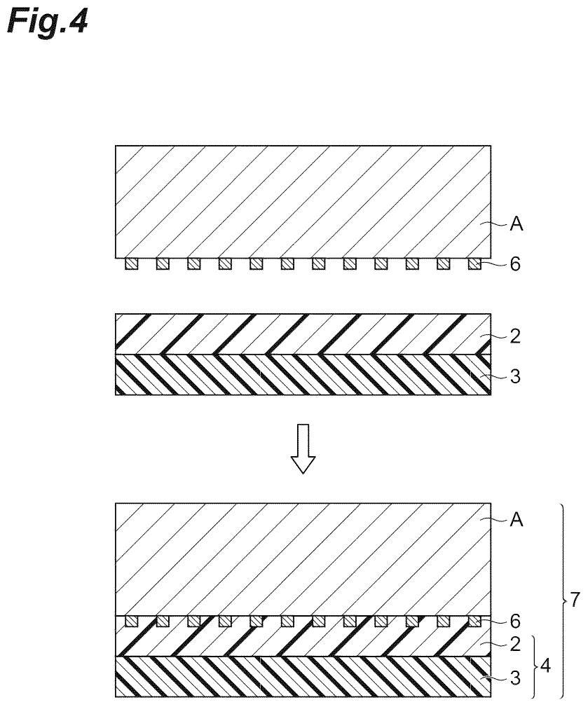

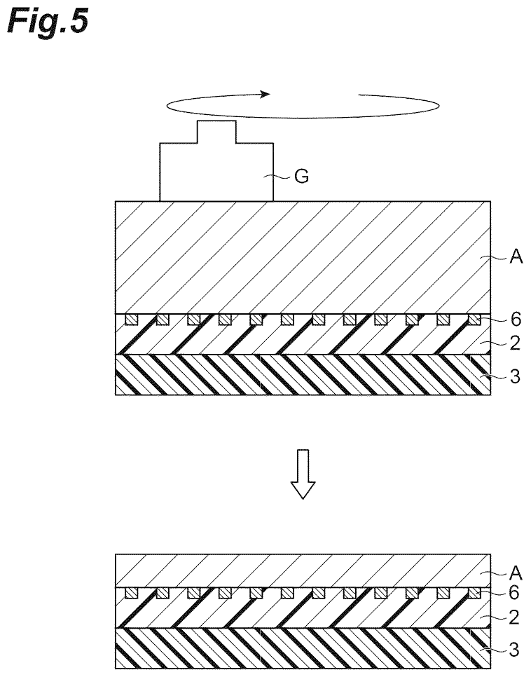

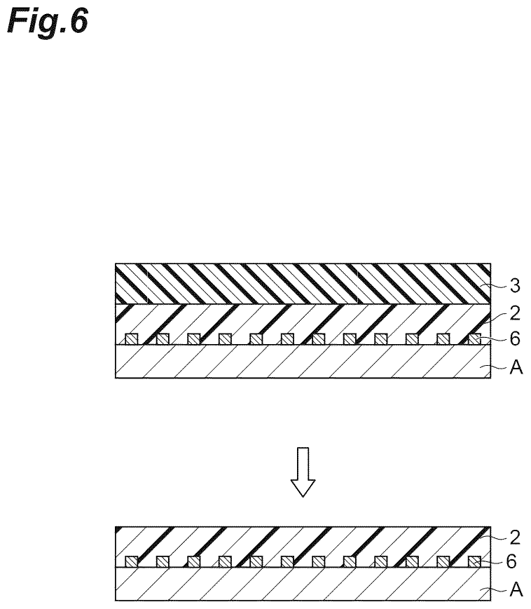

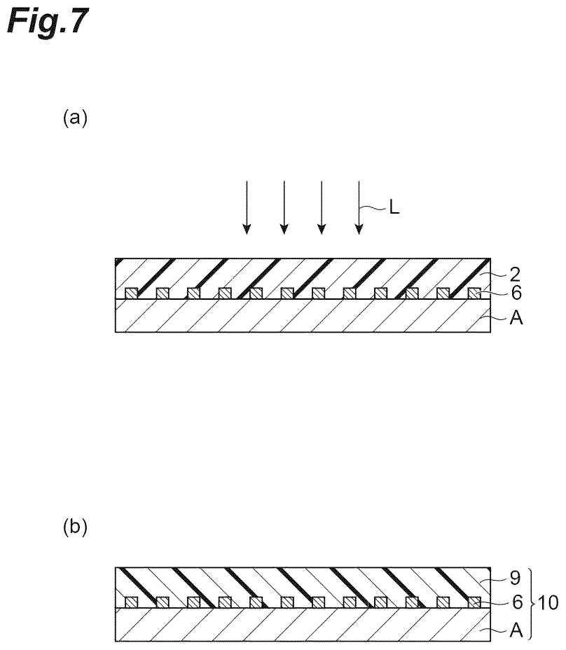

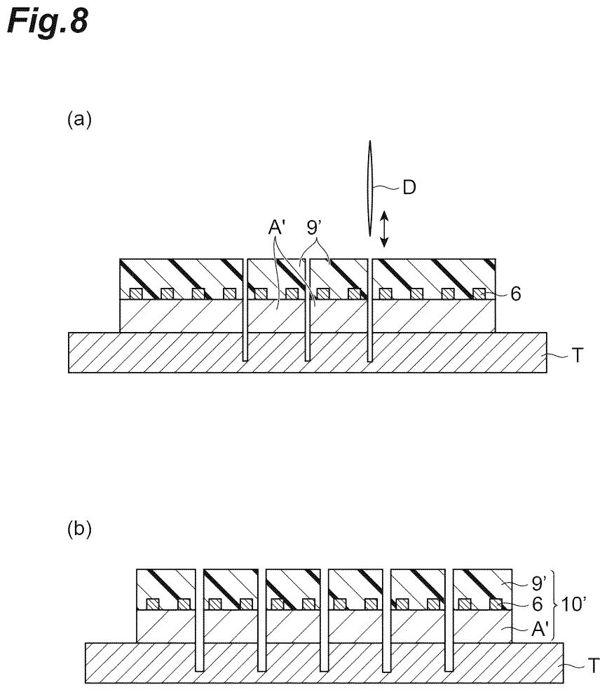

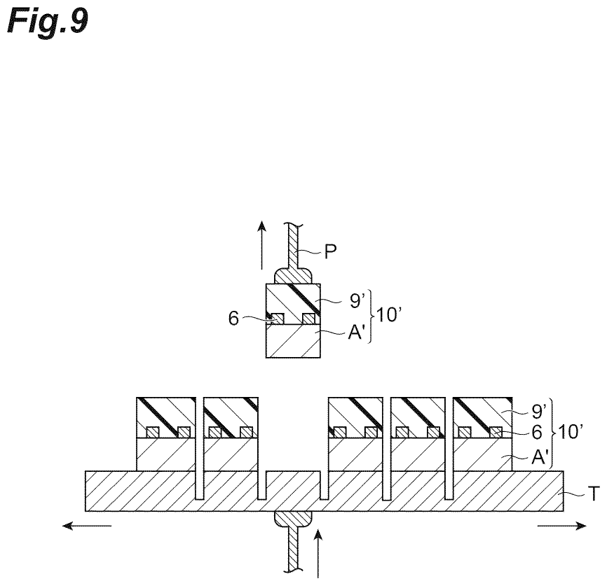

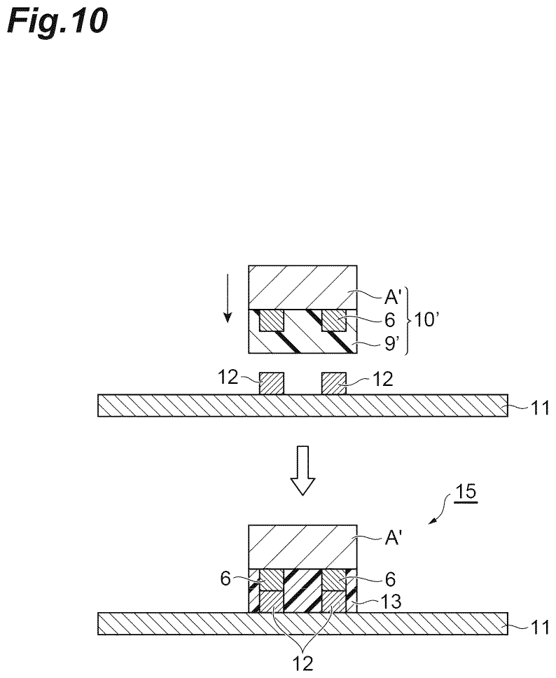

FIG. 4 to FIG. 10 are process cross-sectional views schematically illustrating one embodiment of the method for producing a semiconductor device. The production method of the embodiment includes the following steps (a) to (e).
Step (a): A lamination step of preparing an adhesive tape 4 including an adhesive film 2 and a base material 3 (back-grinding tape), and sticking the adhesive tape 4 from the adhesive film 2 side to a connecting surface of a semiconductor wafer A (see FIG. 4)
Step (b): A back-grinding step of grinding the semiconductor wafer A of a laminated body 7 obtained in step (a) from the opposite side of the adhesive tape 4 (see FIG. 5)
Step (c): A step of removing the base material 3 from the laminated body 7 (see FIG. 6)
Step (d): A light irradiation step of irradiating the adhesive film 2 with light (see FIG. 7)
Step (e): A step of singulating the laminated body 10 including the adhesive film 9 after light irradiation as obtained in step (d) to obtain adhesive film-attached semiconductor chips 10′ (see FIG. 8)
Step (f): A step of picking up the adhesive film-attached semiconductor chip 10′ (see FIG. 9)
Step (g): A step of disposing the adhesive film-attached semiconductor chip 10′ on a connecting surface of a base 11 and heating the assembly to electrically connect a connecting part 6 of the adhesive film-attached semiconductor chip 10′ and a connecting part 12 of the base 11 (see FIG. 10)

### (Step (a))

In step (a), for example, first, an adhesive tape 4 including a back-grinding tape as a base material 3, and a semiconductor wafer A having a connecting part 6 (first connecting part) on one surface are prepared, and the adhesive tape 4 is disposed on a predetermined device such that the surface on the adhesive film 2 side of the adhesive tape 4 and the connecting surface (surface where the connecting part 6 is provided) of the semiconductor wafer A face each other (see (a) in FIG. 4). Next, the adhesive tape 4 is stuck to the connecting surface of the semiconductor wafer A, and a laminated body 7 in which the semiconductor wafer A, the adhesive film 2, and the base material 3 (back-grinding tape) are stacked in this order, is obtained (see (b) in FIG. 4).

Sticking of the adhesive tape 4 can be performed by hot pressing, roll lamination, vacuum lamination, or the like. The supply area and thickness of the adhesive tape 4 are set as appropriate depending on the sizes of the semiconductor wafer and the base, the height of the connecting part, and the like. In FIG. 4, the thickness of the adhesive film 2 is larger than the height of the connecting part 6 of the semiconductor wafer A, and the connecting part 6 is covered by the adhesive film 2; however, the thickness of the adhesive film 2 may be smaller than the height of the connecting part 6.

### (Step (b))

In step (b), for example, the semiconductor wafer A of the laminated body 7 is ground by using a grinder G (see (a) in FIG. 5 and (b) in FIG. 5). The thickness of the semiconductor wafer after grinding may be, for example, 10 μm to 300 μm. From the viewpoints of size reduction and thickness reduction of semiconductor devices, it is preferable to set the thickness of the semiconductor wafer to 20 μm to 100 μm.

### (Step (c))

In step (c), for example, the base material 3 is removed from the laminated body 7 by peeling the base material 3 from the adhesive film 2 (see FIG. 6).

### (Step (d))

In step (d), the adhesive composition in the adhesive film 2 is photocured by irradiating the adhesive film 2 with light (see (a) in FIG. 7 and (b) in FIG. 7). As a result, a laminated body 10 including a low-fluidized adhesive film 9 is obtained. Irradiation with light is performed by, for example, irradiating actinic light L from a light source disposed on the adhesive film 2 side. The actinic light may be, for example, light having a wavelength in the range of 150 to 750 nm (for example, ultraviolet light). As the light source, for example, a low-pressure mercury lamp, a medium-pressure mercury lamp, a high-pressure mercury lamp, an ultrahigh-pressure mercury lamp, a xenon lamp, a metal halide lamp, or an LED light source can be used. The amount of light irradiated can be adjusted as appropriate, and for example, the amount as a cumulative amount of light having a wavelength of 365 nm may be 100 mJ/cm² or more, may be 200 mJ/cm² or more, or may be 300 mJ/cm² or more. The amount of light irradiated may be, for example, 1000 mJ/cm² or less, may be 700 mJ/cm² or less, or may be 500 mJ/cm² or less, as a cumulative amount of light having a wavelength of 365 nm.

### (Step (e))

In step (e), for example, first, a dicing tape 8 is stuck to the semiconductor wafer A side of the laminated body 10, and this is disposed on a predetermined device (see (a) in FIG. 8). Next, the laminated body 10 is diced using a dicing saw D to singulate the laminated body 10, and adhesive film-attached semiconductor chips 10′ including an adhesive film 9′ on a semiconductor chip A′ are obtained (see (b) in FIG. 8). A connecting part 6 is provided on the surface on the adhesive film 9′ side of the semiconductor chip A′. The adhesive film 9′ is formed of the adhesive composition after light irradiation.

### (Step (f))

In step (f), for example, while the adhesive film-attached semiconductor chips 10′ obtained by the above-described dicing are separated apart from each other by expanding (expanding) the dicing tape 8, the adhesive film-attached semiconductor chips 10′ pushed up by a needle N from the dicing tape 8 side are picked up by a pick-up tool P from the adhesive film 9′ side (see FIG. 9). The adhesive film-attached semiconductor chips 10′ thus picked up are delivered to a bonding tool to be used for bonding in step (g).

### (Step (g))

In step (g), for example, first, a base 11 for mounting semiconductor chips, which has a connecting part 12 (second connecting part) on one surface, is prepared, and alignment of an adhesive film-attached semiconductor chip 10′ and the base 11 is performed. Next, the adhesive film-attached semiconductor chip 10′ is disposed on the connecting surface (surface where the connecting part 12 is provided) of the base 11 from the side of the adhesive film 9′, and heated. As a result, the connecting part 6 of the adhesive film-attached semiconductor chip 10′ and the connecting part 12 of the base 11 are electrically connected, and at the same time, a sealing part 13 formed of a cured product of the adhesive film 9′ is formed between the semiconductor chip A′ and the base 11 to seal the connecting part 6 and the connecting part 12, and a semiconductor device 15, which is a joined body of the adhesive film-attached semiconductor chip 10′ and the base 11, is obtained (see FIG. 10). The base 11 is, for example, a semiconductor chip, a semiconductor wafer, or a wiring circuit board.

In a case where solder bumps are used for one of the connecting part 6 and the connecting part 12 (for example, in a case where the connecting part 6 or the connecting part 12 is wiring lines provided with solder bumps), the connecting part 6 and the connecting part 12 are electrically and mechanically connected by solder joining.

Heating in the step (g) may be performed while a semiconductor chip is disposed, or may be performed after a semiconductor chip is disposed. The heating and disposition in the step (g) may be thermocompression bonding. The step (g) may include a step of temporarily fixing after performing alignment (temporary fixing step) and a step of melting the bumps (for example, solder bumps) provided at the connecting part by performing a heating treatment to join the semiconductor chip A′ and the base 11, and at the same time, sealing the connecting parts (sealing step). In the stage of temporary fixing, since it is not necessarily essential to form metal joining, the temporary fixing step can be carried out under a small load at a low temperature for a short time. Therefore, in a case where a temporary fixing step and a sealing step are carried out in the step (g), productivity can be improved, and at the same time, deterioration of the connecting parts can be suppressed.

The load to be applied for temporary fixing is set as appropriate in consideration of the control of the number of connecting parts (bumps), the absorption of height variations in the connecting parts (bumps), the amount of deformation of the connecting parts (bumps), and the like. A larger load is more preferable, from the viewpoint of eliminating voids and making it easier to bring the connecting parts into contact. The load is, for example, preferably 0.009 N to 0.2 N per one connecting part (for example, a bump).

The heating in the sealing step may be carried out by using an apparatus capable of heating to a temperature equal to or higher than the melting point of the metal of the connecting parts. The heating temperature is preferably a temperature at which curing of the adhesive film proceeds, and more preferably a temperature at which the adhesive film is completely cured. The heating temperature and the heating time are set as appropriate.

The heating time in the sealing step varies depending on the type of the metal constituting the connecting parts; however, from the viewpoint that productivity is improved, it is more preferable that the heating time is shorter. In a case where solder bumps are used for the connecting parts, the heating time is preferably 20 seconds or less, more preferably 10 seconds or less, and even more preferably 5 seconds or less. In the case of metal connection of copper-copper or copper-gold, the connection time is preferably 60 seconds or less.

In the sealing step, heating and pressurization may be performed together by using an apparatus capable of heating and pressurization. That is, the heating in the sealing step may be heating by thermocompression bonding. In this case, the load (connection load) is set in consideration of the size of the connecting member, the number of the connecting parts, the variation in the height, the amount of deformation of the connecting parts by pressurization, and the like. The connection load may be, for example, greater than the atmospheric pressure and 1 MPa or less. From the viewpoints of void suppression and improvement in connectivity, a larger load is more preferable, and from the viewpoint of suppressing fillet, a smaller load is more preferable. From these viewpoints, the load is preferably 0.05 to 0.5 MPa. The pressure-bonding time (connection time) may vary depending on the type of the metal forming the connecting parts; however, from the viewpoint of improving productivity, it is more preferable that the pressure-bonding time is shorter. In a case where the connecting parts are solder bumps, the pressure-bonding time is preferably 20 seconds or less, and may be 10 seconds or less or 5 seconds or less. In the direct pressurization using a pressure-bonding machine, since it is difficult for the heat of the pressure-bonding machine to be transferred to fillet, from the viewpoint of easily applying sufficient effect to the fillet, pressurization by air pressure is preferred. Even from the viewpoint of batch sealing and suppression of fillet, it is preferable that the pressurization during heating is performed by pressurization by air pressure (pressurization by a pressure reflow furnace, a pressure oven, or the like).

After the semiconductor chip A′ and the base 11 are connected, a heating treatment may be performed by using an oven or the like to further increase the connection reliability.

Thus, one embodiment of the method for producing a semiconductor device has been described; however, the method for producing a semiconductor device of the present invention is not limited to the above-described method.

For example, in another embodiment, a laminated body that has been produced in advance may be used without carrying out the step (a).

Furthermore, in still another embodiment, a semiconductor wafer whose thickness has been adjusted in advance may be used without carrying out the step (b). In this case, the adhesive film 2 alone, or an adhesive tape including the adhesive film 2 and a base material other than a back-grinding tape (for example, a release film) can be used instead of the adhesive tape 4. In a case where a base material is not used, the step (c) is also unnecessary.

Furthermore, according to still another embodiment, the step (d) may be carried out before the step (c). In a case where the step (d) is carried out before the step (c), the base material 3 may be peeled before sticking, or after sticking, the laminated body to a dicing tape 8. However, from the viewpoint of suppressing the occurrence of a difference in the cured state of the film as the entrance of light to the adhesive film 2 is inhibited by the base material 3 (back-grinding tape), and more easily reducing the fillet amount, it is preferable that the step (d) is carried out after the step (c) and before the step (e).

Furthermore, in another embodiment, a semiconductor chip may be used instead of the semiconductor wafer A. In this case, the adhesive film 2 alone, or an adhesive tape including the adhesive film 2 and a base material other than a back-grinding tape (for example, a release film) can be used instead of the adhesive tape 4. The step (b) and step (e) are unnecessary, and in a case where a base material is not used, the step (c) is also unnecessary.

Furthermore, a wiring circuit board can also be used instead of the semiconductor wafer A. In this case, instead of the step (g), step (g′) of disposing a semiconductor chip on a connecting surface (surface on the connecting part side) where the adhesive film of an adhesive film-attached wiring circuit board is provided, and heating the assembly to electrically connect the connecting part of the semiconductor chip and the connecting part of the wiring circuit board, is carried out. Furthermore, the adhesive film 2 alone, or an adhesive tape including the adhesive film 2 and a base material other than a back-grinding tape (for example, a release film) can be used instead of the adhesive tape 4. Furthermore, the step (b), step (e), and step (f) are unnecessary, and in a case where a base material is not used, the step (c) is also unnecessary.

### EXAMPLES

Hereinafter, the present invention will be described more specifically by way of Examples; however, the present invention is not limited to the Examples.

The details of the materials used in the Examples are as follows.

### (Phenoxy Resin)

ZX-1356-2: Phenoxy resin, manufactured by Tohto Kasei Co., Ltd., trade name, Tg=about 71° C., weight average molecular weight Mw=about 63000

### (Solid Epoxy Resin)

EP1032: Triphenolmethane skeleton-containing polyfunctional solid epoxy, manufactured by Mitsubishi Chemical Corporation, trade name “jER1032H60”, “jER” is a registered trademark (hereinafter, the same)

### (Liquid Epoxy Resin)

YL983U: Bisphenol F type liquid epoxy, manufactured by Japan Epoxy Resins Co., Ltd., trade name
YX7110B80: Flexible epoxy, manufactured by Mitsubishi Chemical Corporation, trade name

### (Imidazole-Based Curing Agent)

2MAOK-PW: 2,4-Diamino-6-[2′-methylimidazolyl-(1′)]-ethyl-s-triazine isocyanuric acid adduct, manufactured by SHIKOKU CHEMICALS CORPORATION, trade name

### (Acrylic Compound)

A-DPH: Dipentaerythritol polyacrylate, manufactured by SHIN-NAKAMURA CHEMICAL Co., Ltd., trade name

### (Photopolymerization Initiator)

Omnirad 127:2-Hydroxy-1-{4-[4-(2-hydroxy-2-methylpropionyl)-benzyl]-phenyl}-2-methyl-propane, manufactured by IGM Resins B.V., trade name (“Irgacure” is a registered trademark; hereinafter, the same)

### (Organic Filler)

EXL-2655: Core-shell type organic microparticles, manufactured by Rohm and Haas Japan KK, trade name

### (Silica Filler)

KE180G-HLA: Silica filler, manufactured by ADMATECHS COMPANY LIMITED, trade name

### (Flux Agent)

2-Methylglutaric acid: Manufactured by Sigma-Aldrich Corporation, melting point=about 78° C.

### Example 1 and Comparative Examples 1 and 2

### (Preparation of Coating Liquid for Forming Adhesive Film)

Among the components shown in Table 1, components other than the photopolymerization initiator were added to an organic solvent (cyclohexanone) such that the NV value ([mass of coating material portion after drying]/[mass of coating material portion before drying]×100) reached 60%, and a mixed liquid was obtained. At this time, the amount of addition of each component was set to the amount (unit: parts by mass) shown in Table 1. Thereafter, beads having a diameter of ϕ1.0 mm and beads having a diameter of ϕ2.0 mm were added to the above-described mixed liquid, and the mixture was stirred for 30 minutes in a bead mill (Fritsch Japan Co., Ltd., planetary type fine grinding mill P-7). The amount of addition of the beads was the same mass as the non-volatile content (total amount of components other than the organic solvent) of the mixed liquid. After stirring, the beads were removed by filtration. Next, when a coating liquid for forming an adhesive film B was prepared, a photopolymerization initiator in the amount (unit: parts by mass) shown in Table 1 was added to the obtained mixture, and the resulting mixture was stirred and mixed. As a result, coating liquid (I) for forming an adhesive film A and coating liquid (II) for forming an adhesive film B were obtained.

TABLE 1

| Adhesive film | | (I) | (II) |
|---|---|---|---|
| Phenoxy resin | ZX-1356-2 | 25 | 30 |
| Solid epoxy resin | EP-1032 | 59.45 | 54.5 |
| Liquid epoxy resin | YL983U | 5.65 | 5.65 |
| Imidazole-based curing | YX7110B80 | 5 | 5 |
| agent | | | |
| Acrylic compound | 2MAOK-PW | 2 | 3 |
| Photoreaction initiator | A-DPH | — | 6.5 |
| Flux agent | irgcure 127 | — | 0.098 |
| 2-Methylglutaric acid | 2-methylglutaric acid | 2 | — |
| Organic filler | EXL2655 | 10 | 10 |
| Silica filler | KE180G-HLA | 64 | 67.3 |

### (Production of Adhesive Tape)

Adhesive tapes of Example 1, Comparative Example 1, and Reference Example 1 were produced using each of the coating liquid (I) and coating liquid (II) produced as described above.

Specifically, first, the coating liquid (I) produced as described above was applied on a release film (manufactured by Teijin Dupont Film Japan Limited, trade name “PUREX A54”) with a small-sized precision coating apparatus (Yasui Seiki Co., Ltd.) such that the film thickness after drying would be 12 μm. Next, the coating film was dried (100° C./10 min) in a clean oven (manufactured by ESPEC CORP.) to form an adhesive film A on the release film. Next, a back-grinding tape was stuck to the adhesive film A, and thereby a release film-attached adhesive tape of Comparative Example 1 including a back-grinding tape, the adhesive film A, and a release film in this order was obtained.

Furthermore, a release film-attached adhesive tape of Example 1 including a back-grinding tape, the adhesive film B, and a release film in this order was obtained in the same manner as described above, except that the coating liquid (II) was used instead of the coating liquid (I).

Furthermore, an adhesive film (adhesive film A or adhesive film B) was formed on a release film in the same manner as in the above-described method for producing the two tapes, except that the coating conditions were changed such that the thickness of the adhesive film after drying would be 6 μm, and a laminated body including a release film and an adhesive film was obtained. Next, the adhesive films of two of the obtained laminated bodies were laminated to form an adhesive film (total thickness 12 μm) having a two-layer configuration including a layer formed from the adhesive film A and a layer formed from the adhesive film B. At this time, the lamination temperature was set to 50° C. Next, the release film on the adhesive film A side (side opposite to the adhesive film B) was peeled, a back-grinding tape was stuck thereto instead, and thereby a release film-attached adhesive tape of Reference Example 1 including a back-grinding tape, an adhesive film having a two-layer configuration, and a release film in this order was obtained.

### <Evaluation>

Connected structures (semiconductor devices) were produced by the following procedure, using the release film-attached adhesive tapes obtained in Example 1, Comparative Example 1, and Reference Example 1. Furthermore, using the obtained connected structures, evaluation of connection reliability (initial conductivity), fillet length, and sealing properties was performed by the methods shown below.

### (Production of Connected Structure)

Each of the release film-attached adhesive tapes produced in Example 1, Comparative Example 1, and Reference Example 1 was cut into a predetermined size (9 mm in length×11 mm in width×12 μm in thickness), the release film was removed, and then the adhesive tape was stuck to a surface (connecting surface) of a solder bump-attached semiconductor chip (chip size: 8.0 mm in length×10.0 mm in width×0.05 mm in thickness, bump height: copper pillar+solder about 12 μm in total, number of bumps 1914) to obtain a laminated sample. In Example 1 and Reference Example 1, two each of the above-described laminated samples were prepared.

With regard to the laminated samples obtained using the release film-attached adhesive tapes of Example 1 and Reference Example 1, the adhesive film was irradiated with light. At this time, one of the two laminated samples was irradiated with light through the back-grinding tape, whereas for the other laminated sample, the back-grinding tape was removed, and then the exposed surface was irradiated with light. Furthermore, regarding the light irradiation, a metal halide lamp was used as a light source, and the amount of irradiation of light having a dominant wavelength of 365 nm at an illuminance of 70 mW was 250 mJ/cm².

Next, using a film mounting apparatus “FCB3” (manufactured by Panasonic Corporation, product name), the above-described laminated sample (for Example 1 and Reference Example 1, the laminated sample after light irradiation) was mounted on a wafer base material (wafer base material: 100 μm thick, copper wiring lines: 6 μm thick) from the adhesive film side. The mounting was performed under the conditions in which the highest attained temperature of the compression head temperature was 260° C., the compression time was 20 seconds, and the compression pressure was 110 N. As a result, connected structures (semiconductor devices) in which the wafer base material and the solder bump-attached semiconductor chip were daisy-chain connected, were obtained.

### (Connection Reliability)

The connection reliability (initial conductivity) was evaluated by measuring the connection resistance value of a 40 μm-pitch area of the connected structure obtained as described above, by using a multimeter (manufactured by ADVANTEST CORPORATION, trade name “R6871E”). A case in which the connection resistance value was 60.0Ω or more and 85.0Ω or less was rated as “A”; a case in which the connection resistance value was more than 85.0Ω and 100Ω or less was rated as “B”; and a case in which the connection resistance was more than 100Ω, a case in which the connection resistance was less than 60.0Ω, and a case in which the resistance value was not displayed due to connection failure, were all rated as “C”. When the rating was B, it was determined that the connection reliability was sufficient, and when the rating was A, it was determined that the connection reliability was satisfactory. The results are shown in Table 2.

### (Fillet Amount)

The connected structure obtained as described above was observed from the semiconductor chip side by using a digital microscope VHX-6000 (manufactured by KEYENCE CORPORATION), and the length of adhesive overflowing from the four sides around the semiconductor chip (fillet) was measured. As the length of the fillet on each side, the maximum value of the shortest distance from the edge of the overflowing adhesive to the semiconductor chip was employed. The fillet amount was evaluated based on the average value of the length of fillet measured at each of the four sides. When the average value was less than 400 μm, it was determined that the amount of fillet generated had been sufficiently reduced. The results are shown in Table 2. The numerical value in the table represents an average value of the length of the above-described fillet.

TABLE 2

| | | | Comparative | Reference | |
|---|---|---|---|---|---|
| Adhesive | Example 1 | | Example 1 | Example 1 | |
| film | B (single layer) | | A (single layer) | A/B (two-layer) | |
| Conditions | With BG | Without | — | With BG | Without |
| of light | | BG | | | BG |
| irradiation | | | | | |
| (250 mJ) | | | | | |
| Connection | A | B | A | A | A |
| reliability | | | | | |
| Fillet | 397 | 293 | 463 | 465 | 392 |
| amount | | | | | |
| (μm) | | | | | |

In the table, the term “With BG” means that light irradiation was performed in the presence of a back-grinding tape, and the term “Without BG” means that light irradiation was performed after removing the back-grinding tape.

### REFERENCE SIGNS LIST

1: release film, 2: adhesive film, 3: base material, 4: adhesive tape, 5: release film-attached adhesive tape, 6: connecting part (first connecting part), 7, 10: laminated body, 9: adhesive film after photocuring, 10′: adhesive film-attached semiconductor chip, 11: base, 12: connecting part (second connecting part), 13: sealing part, 15: semiconductor device, 20: semiconductor chip, 25: wiring line (first connecting part and second connecting part), 30: base, 40: connecting bump, 42: bump (first connecting part and second connecting part), 44: through electrode, 50: sealing part, 60: interposer, 100, 200, 300: semiconductor device, A: semiconductor wafer, A′: semiconductor chip.

1. An adhesive film used for joining a semiconductor chip and a base and sealing a gap between the semiconductor chip and the base,
the adhesive film being a single layer film formed from an adhesive composition having photocurability and thermosetting properties.

2. The adhesive film according to claim 1, wherein the adhesive composition comprises a photopolymerizable compound, a photopolymerization initiator, a thermosetting resin, and a thermal curing agent.

3. The adhesive film according to claim 2, wherein the photopolymerizable compound is a radically polymerizable compound, and the photopolymerization initiator is a photoradical polymerization initiator.

4. The adhesive film according to claim 3, wherein the radically polymerizable compound comprises a (meth)acrylic compound.

5. The adhesive film according to claim 2, wherein the thermosetting resin comprises an epoxy resin.

6. The adhesive film according to claim 5, wherein the thermal curing agent comprises an imidazole-based curing agent.

7. The adhesive film according to claim 6, wherein the imidazole-based curing agent has a triazine ring.

8. The adhesive film according to claim 2, wherein a mass ratio of a content of the thermosetting resin with respect to a content of the photopolymerizable compound in the adhesive composition is 3 to 11.

9. An adhesive tape comprising:
the adhesive film according to claim 1; and
a back-grinding tape provided on the adhesive film.

10. A release film-attached adhesive tape comprising:
the adhesive tape according to claim 9; and
a release film provided on the adhesive tape, the release film being provided on an opposite side of the back-grinding tape as viewed from the adhesive film.

11. A method for producing a semiconductor device, the method comprising:
irradiating the adhesive film according to claim 1 with light; and
heating and joining a semiconductor chip and a base for mounting the semiconductor chip, in a state in which the semiconductor chip and the base are arranged, with the adhesive film after light irradiation interposed therebetween, such that connecting parts thereof face each other,
wherein the light is irradiated in a state in which the adhesive film is stuck to a connecting surface of the semiconductor chip or a precursor thereof, or a connecting surface of the base or a precursor thereof.

12. The method for producing a semiconductor device according to claim 11, further comprising:
preparing an adhesive tape comprising the adhesive film and a back-grinding tape provided on the adhesive film, and sticking the adhesive tape from a side of the adhesive film to a connecting surface of a precursor of the semiconductor chip or a precursor of the base; and
grinding the precursor to which the adhesive tape is stuck, from an opposite side of the adhesive tape.

13. The method for producing a semiconductor device according to claim 12, wherein the light is irradiated after removing the back-grinding tape after grinding the precursor.

14. A semiconductor device comprising:
a semiconductor chip having a first connecting part;
a base having a second connecting part electrically connected to the first connecting part; and
a sealing part adhering the semiconductor chip to the base and filling a gap between the semiconductor chip and the base,
wherein the sealing part is a cured product of the adhesive film according to claim 1.
